(19) United States
(12) Patent Application Publication
(10) Pub. No.: US 2009/0317962 A1
(43) Pub. Date: Dec. 24, 2009

(54) METHOD FOR MANUFACTURING SEMICONDUCTOR DEVICE, SEMICONDUCTOR PRODUCTION EQUIPMENT AND STORAGE MEDIUM

(75) Inventor: Shuichi NODA, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/482,506

(22) Filed: Jun. 11, 2009

(30) Foreign Application Priority Data
Jun. 24, 2008 (JP) 2008-164731

(51) Int. Cl. H01L 21/20; B05C 11/00

(52) U.S. Cl. 438/488; 118/663; 257/E21.09

(57) ABSTRACT

A method for manufacturing a semiconductor device, semiconductor production equipment, and a storage medium, which suppress abnormal arc discharge occurring when plasma is excited while preventing misalignment of a substrate placed on an electrostatic chuck, are provided. The method includes a first process in which a substrate is placed on an electrostatic chuck in a reaction container and a first electrostatic chuck voltage is applied to the electrostatic chuck to absorb the substrate onto the electrostatic chuck, a second process in which the first electrostatic chuck voltage is reduced to a second electrostatic chuck voltage, a third process in which a high-frequency voltage is applied between parallel plate electrodes in the reaction container to generate plasma, and a fourth process in which the second electrostatic chuck voltage is changed to a third electrostatic chuck voltage higher than the second electrostatic chuck voltage.

### BACKGROUND OF THE INVENTION

1. Field of the Invention

The present invention relates to a method for manufacturing a semiconductor device, semiconductor production equipment, and a storage medium, and more particularly to semiconductor production equipment and a method for manufacturing a semiconductor device wherein an insulating substrate is fixed in the equipment using an electrostatic chuck mechanism, and a related storage medium.

2. Description of the Related Art

A plasma treatment apparatus such as plasma etching equipment or plasma CVD equipment, which is used to manufacture fine structures such as various semiconductor elements, generally includes an electrostatic chuck mechanism in order to increase the accuracy of processing of a substrate.

The electrostatic chuck mechanism places a substrate on a stage, in which temperature, RF power applied for plasma excitation, or the like are controlled uniformly throughout the surface of the stage with high accuracy, and applies a high DC voltage (HV) to firmly fix the substrate through electrostatic attractive force.

Using the electrostatic chuck mechanism, the temperature of the substrate, the state of plasma directly above the substrate, and the like are controlled with high accuracy to accomplish stable and highly accurate processes.

Although an electrode for applying a high DC voltage HV included in the electrostatic chuck mechanism is covered with an insulating layer having a sufficient thickness for achieving high voltage resistance and is not in direct contact with conductive plasma, abnormal arc discharge, which will also be referred to as “arcing”, may occur in gas-phase plasma due to the high DC voltage HV.

In an effort to suppress such arcing, a method has been suggested in which a high DC voltage HV is applied to the electrode to electrostatically chuck a substrate after the substrate is exposed to weak plasma in advance, and thereafter process plasma is excited (see Japanese Patent Application No. 2007-208302).

Another method has also been suggested in which a high negative DC voltage HV is applied before a high positive DC voltage HV is applied to excite plasma (see Japanese Patent Application No. 2001-15581).

There have also been suggested a method in which a high DC voltage HV is applied after plasma is excited (see Japanese Patent Application Nos. Heisei 6-112160 and 10-27780) and a method in which plasma is temporarily removed after plasma is excited and a high DC voltage HV is applied, and a He gas for cooling the substrate is introduced and plasma is re-excited (see Japanese Patent Application No. 2007-227604).

One advantage of the method described in Japanese Patent Application No. 2007-208302 is that arcing is suppressed by reducing the amount of charge accumulated on a substrate. However, this advantage may not be obtained depending on the material of the substrate. For example, when a substrate having insulating properties such as a Silicon On Sapphire (SOS) substrate is used, charge mobility is reduced since the substrate has low electric permittivity and it is difficult to reduce the amount of charge accumulated on the substrate, resulting in occurrence of arcing.

In the method described in Japanese Patent Application No. 2001-15581, arcing may be suppressed by applying a high negative DC voltage HV before plasma is excited taking into consideration that particles mixed into gases when the gases are introduced have positive charge. However, if plasma is excited while a high DC voltage HV is applied, a large potential difference occurs at the moment when plasma is excited and arcing may occur due to the concentration of electric field at the moment.

In the methods described in Japanese Patent Application Nos. Heisei 6-112160 and 10-27780 and Japanese Patent Application No. 2007-227604, the substrate has not yet been etched when plasma is generated (i.e., when etching is initiated), the uniformity of etching is reduced although the electric field concentration described above does not occur. These methods are also subject to negative effects caused by the material of the substrate.

That is, compared to a silicon substrate, the insulating substrate has low thermal conductivity and the temperature of the substrate is not uniform throughout the surface of the substrate. In addition, since the SOS substrate is a lamination of a sapphire substrate, which is an insulating substrate, and a silicon single-crystal layer and is not made of a single material unlike the silicon substrate, voltage change in each location of the SOS substrate is significant and thus arcing easily occurs.

In addition, since the insulating substrate has low electric permittivity, slight floating of the substrate from the electrostatic chuck causes a local RF impedance increase, resulting in an uneven distribution of applied RF bias power on the surface of the substrate. The unevenness of the distribution of RF bias power increases as the frequency of bias RF of the electrostatic chuck decreases. In addition, since such floating of the substrate may result in misalignment of the substrate from the electrostatic chuck, there is a need to increase voltage applied to the electrostatic chuck in order to prevent floating of the substrate.

### SUMMARY OF THE INVENTION

Therefore, the present invention has been made in view of the above problems, and it is an object of the present invention to provide a method for manufacturing a semiconductor device, semiconductor production equipment, and a storage medium which suppress abnormal arc discharge occurring when plasma is excited while preventing misalignment of a substrate placed on an electrostatic chuck.

In accordance with an aspect of the present invention, the above and other objects can be accomplished by the provision of a method for manufacturing a semiconductor device, the method including a first process in which a substrate is placed on an electrostatic chuck in a reaction container and a first electrostatic chuck voltage is applied to the electrostatic chuck to absorb the substrate onto the electrostatic chuck, a second process in which the first electrostatic chuck voltage is reduced to a second electrostatic chuck voltage, a third process in which a high-frequency voltage is applied between parallel plate electrodes in the reaction container to generate plasma, and a fourth process in which the second electrostatic chuck voltage is changed to a third electrostatic chuck voltage higher than the second electrostatic chuck voltage.

In accordance with another aspect of the present invention, there is provided semiconductor production equipment including a reaction container, an upper electrode provided in the reaction container, a lower electrode provided opposite the upper electrode in the reaction container, a first high-frequency power source that applies high-frequency power to the upper electrode, a second high-frequency power source that applies high-frequency power to the lower electrode, an electrostatic chuck that electrostatically absorbs a substrate, a DC power source that applies an electrostatic chuck voltage to the electrostatic chuck, a reactive gas supply system that supplies a reactive gas for generating plasma into the reaction container, and a controller that performs the method for manufacturing a semiconductor device described in any one of claims 1 to 5.

In accordance with another aspect of the present invention, there is provided a storage medium storing a program that is executed by a controller of semiconductor production equipment including a reaction container, wherein the program causes the controller to perform the method for manufacturing a semiconductor device described in any one of claims 1 to 5.

As described above, the present invention provides a method for manufacturing a semiconductor device, semiconductor production equipment, and a storage medium which can suppress abnormal arc discharge occurring when plasma is excited while preventing misalignment of a substrate placed on an electrostatic chuck.

### DETAILED DESCRIPTION OF THE PREFERRED EMBODIMENTS

<Method for Manufacturing Semiconductor Device>

### Embodiment 1

In the first embodiment, using the plasma etching equipment shown in FIG. 1, surface treatment is performed on a treatment subject substrate based on a sequence shown in FIG. 2. The first embodiment is described below with reference to FIGS. 1 and 2.

[First Process]

First, a substrate 20 is placed on an electrostatic chuck 18. Then, after a reaction container 15 is evacuated, a first electrostatic chuck voltage, which will also be referred to as “HV1” as appropriate, is applied from a DC power source 23 to the electrostatic chuck 18.

At this state, the substrate 20 is absorbed onto a surface of the electrostatic chuck 18 through electrostatic attractive force. This electrostatic chuck voltage can be adjusted appropriately according to the material of the substrate 20 or the like and may be adjusted to any level, without being limited to a specific level, provided that a cooling gas described below does not leak when the substrate 20 is absorbed onto the electrostatic chuck 18 through the electrostatic chuck voltage such that the cooling gas is sealed on the rear surface of the substrate 20.

Thereafter, in order to increase thermal conductivity of the interface surface of the electrostatic chuck 18 and the substrate 20 and to control temperature on the interface surface at a uniform level, for example, a He gas is introduced to the interface surface through a rear-surface gas introduction path 28 provided at the rear side of the substrate 20 to stably control the pressure of He gas on the rear surface of the substrate 20 at a predetermined pressure (where the control mechanism is not illustrated).

Here, due to electrostatic attractive force applied to the substrate 20, the rear-surface He gas does not leak into the reaction container 15 and is instead sealed on the rear surface of the substrate 20 and therefore the flow rate of introduction of He gas is controlled to nearly zero after the pressure of He gas on the rear surface reaches the predetermined pressure.

Simultaneously with the introduction of the rear-surface He gas, reactive gases required for the plasma etching process (for example, C₄F₈, O₂, Ar, SF₆,r CF₄, CHF₃, CI₂, BCI₃, etc.) are introduced at a constant flow rate into the reaction container 15 from a reactive gas supply system 32 provided at the side of the upper electrode 16 and the reaction container 15 is then evacuated through an exhaust system 34 so that the inner pressure of the reaction container 15 reaches a predetermined pressure.

[Second Process]

Before a third process in which a first high-frequency power source 21 applies a predetermined high-frequency power, which will also be referred to as an “RF output” as appropriate, to the upper electrode 16 to excite plasma 19, the electrostatic chuck voltage is reduced from HV1 to a second electrostatic chuck voltage, which will also be referred to as “HV2” as appropriate, and the reduced electrostatic chuck voltage is maintained for a very short time (“t2” in FIG. 2).

In this process, the electrostatic chuck voltage for the electrostatic chuck is suppressed immediately before plasma is generated, and therefore it is possible to suppress a local floating voltage, which is generated between an SOI layer and a silicon layer due to the high-voltage output, at a low level. Accordingly, it is possible to suppress the width of voltage variation when a short-circuit to earth instantly occurs due to plasma generation, thereby suppressing arcing.

In addition, since the high-voltage output applied to the electrostatic chuck is reduced only at the moment when plasma is generated, it is possible to fix the substrate onto the electrode with a sufficient absorbing force, constantly from the start to end of the plasma process. Accordingly, the distribution of temperature on the surface of the substrate and high-frequency impedance of the substrate are made uniform immediately before the plasma etching is performed and thus it is possible to make the process more stable, thereby achieving high quality.

The value of HV2 in the first embodiment needs to be lower than HV1 and preferably has an output level which does not cause arcing when plasma is excited in the third process. Since the generation of arcing is due to factors such as the material of the substrate 20 and reactive gases used to excite plasma, it is also possible to appropriately adjust these factors.

[Third Process]

Then, the first high-frequency power source 21 connected to the upper electrode 16 as shown in FIG. 1 applies a predetermined RF output to the upper electrode 16 and a second high-frequency power source 22 connected to a lower electrode 17 applies a predetermined RF output to the lower electrode 17. That is, a high-frequency voltage is applied between the two parallel planar electrodes, i.e., the upper electrode 16 and the lower electrode 17, to generate plasma.

[Fourth Process]

Finally, after the time “t2” elapses, the electrostatic chuck voltage is increased from HV2 to HV3 with the RF output being applied. This is in order to reliably avoid movement of the substrate during surface treatment of the substrate 20 since HV2 is the lowest voltage for electrostatic absorption as described above.

It is preferable that the electrostatic chuck voltage HV3 be equal to HV1 applied in the first process since it needs to be a voltage which produces a sufficient electrostatic absorbing force for the substrate 20. Voltage control will also be easy if HV1 and HV3 are set to the same voltage.

By performing the processes described above, it is possible to perform surface treatment of the substrate 20 in a desired etching condition without causing arcing.

### Embodiment 2

The second embodiment modifies the structure of the treatment subject substrate of the first embodiment into a more preferable structure as follows. The processes of the second embodiment are identical to those of the first embodiment.

The treatment subject substrate of the second embodiment preferably has a polysilicon layer at a rear surface thereof or both the rear and side surfaces.

Since the treatment subject substrate having such a structure is not formed of a single material unlike a silicon substrate, arcing easily occurs. However, in the second embodiment, HV2 is reduced to a voltage which does not cause arcing as in the first embodiment. Accordingly, it is possible to suppress the occurrence of arcing even though the treatment subject substrate has the structure of the second embodiment.

An example of the substrate of the second embodiment is a substrate 20 as shown in FIG. 1, which includes an insulating substrate 11, an SOI layer 12 layered on the insulating substrate 11, a polysilicon layer 13 covered on a rear surface or on the rear and side surfaces of the insulating substrate 11. Here, the SOI layer 12 is a single-crystal silicon layer formed on an insulating film and is referred to as an “SOS substrate” when the insulating film is sapphire.

It is preferable that the thickness of the polysilicon layer 13 be equal to or greater than 10 nm and equal to or less than 200 nm taking into consideration both the need to form a continuous layer without being affected by the roughness or the like of the rear surface of the substrate and the need to minimize the effects of the stress of the film.

The polysilicon layer 13 is provided to bring the substrate 20 into a floating state and it is preferable that the polysilicon layer 13 be doped with an impurity taking into consideration the need to reduce electrical resistance. For example, the impurity is P and it is preferable that the dopant concentration be equal to or greater than 0.5×10²⁰ ion/cm³ and equal to or less than 4×10²⁰ ion/cm³.

A silicon insulating film, separate from the single-crystal silicon layer, may also be provided between the insulating substrate 11 and the polysilicon layer 13. Since the insulating substrate 11 is transparent when it is sapphire, the provision of the silicon insulating film has an advantage of significantly reducing optical transmittance due to light interference through such multi-layer films.

In order to achieve such an advantage, it is more preferable that 2 to 6 films be layered. In addition, since such layered films only need to be made of materials having different refractive indices, films of materials that are widely used in Si semiconductor processes, for example films made of SiN, Al₂O₃, TaO₃, or the like, may be formed as the reflective films.

It is preferable that the material of the insulating substrate 11 used in the substrate 20 be a ceramic or an organic material having high strength and thermal resistance.

Examples of the ceramic include quartz, sapphire, alumina, TiN, SIC, and BN.

Examples of the organic material having thermal resistance and high strength include polycarbonate, polyarylate, and polyimide. The material of the substrate may be appropriately selected from these materials according to usage and may also be selected from various other materials according to a target device which employs the substrate.

In the present invention, quartz is especially preferable among such materials, taking into consideration the need to achieve thermal resistance and the need to add impurities for forming a semiconductor element on the insulating substrate 11.

The substrate 20 may be shaped such that a chamfered portion is formed at an upper edge portion of the insulating substrate 11 near to the SOI layer 12. The chamfered portion may have an R-surface shape or a C-surface form and may have any other shape provided that, when the silicon insulating film is formed, it prevents the silicon insulating film from being layered on the end portion of the surface of the substrate.

### Embodiment 3

The third embodiment is similar to the first embodiment, except that the electrostatic chuck voltage and the time required for the second to fourth processes are modified to preferable ones described below.

“HV2” and “t2” in FIG. 2 denote the magnitude of the electrostatic chuck voltage and the time during which HV2 is maintained as described above, respectively, which can be appropriately adjusted based on results described below.

For example, as shown in FIG. 1, the polysilicon layer 13 which is doped with an impurity such as phosphorus is covered on the rear surface or on the rear and side surfaces of the insulating substrate 11 in the substrate which includes the insulating substrate 11 and the SOI layer 12.

When surface treatment is performed on the substrate 20, the electrostatic chuck voltage applied to the polysilicon layer 13 instantly drops to zero immediately after plasma is generated. This generates a potential difference between the SOI layer 12 and the polysilicon layer 13. This potential difference exceeds 1000V and the is concentration of electric field on the corresponding location due to the potential difference can be considered a cause of the arcing.

This potential difference can be measured by measuring a voltage of each location using a digital storage oscilloscope, after connecting high-impedance probes 26 and 27 to the polysilicon layer 13 and the SOI layer 12 shown in FIG. 1 as shown in FIG. 3, and then estimating the time dependency of the measured voltage of each location. The results are shown in FIGS. 4A and 4B.

FIG. 4A illustrates the time dependency of the voltage of the polysilicon layer 13 of the substrate 20 and FIG. 4B illustrates the time dependency of the voltage of the SOI layer 12 of the substrate 20. The values of these voltages correspond to changing potentials of the polysilicon layer 13 and the SOI layer 12 relative to that of the reaction container 15 that is grounded as shown in FIG. 3.

The substrate 20 is in an electrical floating state since the entirety of the substrate 20 is absorbed onto the surface of the electrostatic chuck 18 which is covered with an insulating (or dielectric) body which is a part of the electrostatic chuck 18.

As shown in FIG. 4A, the voltage of the polysilicon layer 13 on the rear surface of the substrate 20 which is in contact with the surface of the electrostatic chuck 18 reaches a uniform level after the polysilicon layer 13 is absorbed onto the electrostatic chuck 18 through the electrostatic chuck voltage at the moment when the electrostatic chuck voltage is applied.

On the other hand, a potential change of tens of volts is observed at the SOI layer 12 due to electromagnetic induction at the moment when the electrostatic chuck voltage is applied as shown in FIG. 4B. However, the potential of the, SOI layer 12 is maintained at nearly 0V since the SOI layer 12 is insulated with the sufficient insulation thickness of the substrate 20.

When plasma is excited with the electrostatic chuck voltage being applied, the polysilicon layer 13 returns to 0V after overshooting to a polarity-reversed voltage with the opposite polarity to the electrostatic chuck voltage upon excitation of plasma as shown in FIG. 4A.

On the other hand, the potential of the SOI layer 12 exhibits a nearly uniform level of about 0V although a small potential change is observed at the moment when plasma is excited as shown in FIG. 4B.

The potential of the polysilicon layer 13 is 0V after plasma is excited because the polysilicon layer 13 which is in a floating state is short-circuited to earth through the plasma 19 as shown in FIG. 5.

Since a large potential difference instantly occurs between the polysilicon layer 13 and the SOI layer 12 at the moment when plasma is excited as shown in FIGS. 4A and 4B, we can infer that this potential difference is a cause of the arcing.

That is, we can infer that arcing is mainly caused by a potential difference that occurs between structures (the polysilicon layer 13 and the SOI layer 12 in this example) present in plasma due to charge-up of the structures.

We can also consider that arcing is generated by a potential difference due to a lack of uniformity, at microscopic scale, of plasma involving floating particles in the reaction container 15. However, since the amount of charge accumulated in the substrate 20, whose potential is in a floating state, is small, we can easily infer that even the application of a large potential difference does not cause the emission of an amount of energy which can destroy the substrate 20.

Accordingly, even though arcing 40 is generated in a region between the polysilicon layer 13 and the SOI layer 12, we can infer that the main cause of the arcing 40 is not charge present on the substrate 20 but is charge-up between the structures present in plasma.

Accordingly, in order to efficiently suppress arcing, the electrostatic chuck voltage can be suppressed to a low level before plasma is excited to reduce the overshooting voltage.

Although it is preferable that the time length of t2 for suppressing arcing be minimized in order to prevent misalignment of the substrate 20, there is a need to set the time length of t2 to a sufficient length, taking into consideration the operating time of HV1 or the like. The range of t2 is preferably equal to or greater than 0.1 seconds and equal to or less than 10 seconds.

In addition, it is especially preferable that the minimum value of t2 be equal to the length of time from a time point A at which the voltage starts sharply changing to a time point B at which the voltage overshoots as shown in FIG. 4A. On the other hand, it is especially preferable that the maximum value of t2 be equal to the length of time from the time point A to a time point C at which the voltage reaches 0V as shown in FIG. 4A. That is, it is especially preferable that the range value of t2 be equal to or greater than 0.5 seconds and equal to or less than 2.5 seconds, taking into consideration the operating time of HV1 or the like as described above.

In addition, it is preferable that the maximum value of the range of HV2 for suppressing arcing be equal to the highest level of HV2 which does not cause arcing described above and the minimum value thereof be equal to the lowest level of HV2 which allows the substrate 20 to be constantly absorbed onto the electrostatic chuck 18. That is, the range of the absolute value of HV2 is preferably equal to or greater than 1000V and equal to or less than 2000V.

### Embodiment 4

The method for manufacturing a semiconductor device according to the fourth embodiment is similar to that of the first embodiment, except that the method further includes a process for introducing cooling gas and reactive gas before the third process.

It is preferable that cooling gas and reactive gas are introduced several seconds before plasma is generated in order to make the temperature of the substrate 20 uniform throughout the surface of the substrate 20.

The time at which cooling gas and reactive gas are introduced may be appropriately adjusted according to the material, the plate pressure, or the like of the substrate taking into consideration the fact that the time that elapses until the temperature of the substrate becomes uniform throughout the surface of the substrate varies depending on the material, the plate pressure, or the like of the substrate. Particularly, it is preferable that the time at which cooling gases are introduced be prior to the third process in which plasma is generated in order to cool the substrate 20. If cooling gases are introduced after the third process, the temperature of the substrate may be raised since plasma has already been generated, especially when the used substrate is one having a low thermal conductivity such as an SOS substrate.

In addition, it is preferable that reactive and cooling gases be introduced at the same time for the purpose of instantly making the substrate temperature uniform.

<Recording Medium and Semiconductor Production Equipment>

FIG. 1 illustrates a configuration of plasma etching equipment 10 which can be used in the first to fourth embodiments.

As shown in FIG. 1, the plasma etching equipment 10 is dual-frequency parallel plate reactive ion etching equipment which includes a reaction container 15 that can be maintained at vacuum and an upper electrode 16 and a lower electrode 17 that are provided in the reaction container 15.

A first high-frequency power source 21 of, for example 27 MHz, is connected to the upper electrode 16 and a second high-frequency power source 22 of, for example 800 MHz, is connected to the lower electrode 17. Plasma is generated by applying a high-frequency voltage between the two plate electrodes, i.e., the upper electrode 16 and the lower electrode 17.

An electrostatic chuck 18 is mounted on the lower electrode 17 and the lower electrode 17 is provided with a power source circuit including a DC power source 23 that is connected to the lower electrode 17 through a low pass filter 24. An electrostatic chuck voltage generated from the DC power source 23 is applied to an electrode 25 embedded in the electrostatic chuck 18 to electrostatically absorb a substrate 20 that is placed on the surface of the electrostatic chuck 18 with an insulating layer disposed therebetween.

A rear-surface gas introduction path 28 of the rear side of the substrate 20 is provided in the electrostatic chuck 18 to control the temperature of the substrate 20.

A reactive gas supply system 32 and an exhaust system 34 are provided for the reaction container 15 to introduce gases such as reactive gases into the reaction container 15 and to maintain the inner pressure of the reaction container 15 at a specific level, respectively.

The plasma etching equipment 10 includes a controller (not shown) which synchronizes and controls the timings of the application of the electrostatic chuck voltage, the RF output, and the provision of reactive and cooling gases for generating plasma.

This controller (not shown) includes a microcomputer and includes an arithmetic processing unit such as a CPU and a storage medium which stores a control program that causes the arithmetic processing unit to perform a series of process-related operations.

The control program can transmit signals for performing control operations such as a control operation for opening or closing valves (not shown) provided on the reactive gas supply system 32, the exhaust system 34, or the like for introducing reactive gases for plasma generation into the reaction container 15; a control operation for turning the output of an electrostatic chuck voltage from the first high-frequency power source 21 and the second high-frequency power source 22 on or off; a control operation for opening or closing valves (not shown) for introducing cooling gases to the rear surface of the substrate 20; and a control operation for detecting the flow rate of cooling gases, determining whether or not the flow rate of cooling gases exceeds a predetermined level, and controlling the provision of cooling gases based on the determination.

Examples of the storage medium which provides the control program include a RAM, an NV-RAM, a floppy disk, a hard disk, an optical disc, a magneto-optical disc, a CD-ROM, an MO, a CD-R, a CD-RW, a DVD such as a DVD-ROM, a DVD-RAM, a DVD−RW, or a DVD+RW, a magnetic tape, a nonvolatile memory card, a ROM, and any other type of medium which can store the control program.

The control program may also be downloaded from another computer or database like (not shown) connected to the Internet, a commercial network, or a local area network.

The functions of the above embodiments may be implemented not only by allowing the computer to read and execute the control program but also by allowing an Operating System (OS) or the like running on the computer to perform all or part of the actual processes based on instructions of the control program.

The functions of the above embodiments may be implemented by writing the control program read from the storage medium to a memory provided on a function expansion unit board inserted in the computer or provided in a function expansion unit connected to the computer and then causing a CPU or the like, provided in the function expansion board or the function expansion unit, to perform all or part of the actual processes based on instructions of the control program.

The control program may be provided in a form such as objective codes, a control program executed by an interpreter, or script data provided to an Operating System (OS).

The semiconductor production equipment according to the present invention can be applied not only to the etching equipment as described above but also to CVD equipment.

### Embodiment 5

Arcing easily occurs in equipment which generates plasma by supplying high-frequency power to a pair of parallel plate electrodes that are provided below and above, opposing each other. In this embodiment, a treatment subject substrate is subjected to surface treatment through the above-described method which can suppress the occurrence of arcing even when such equipment in which arcing easily occurs is used. The following is a detailed description.

In this embodiment, a treatment subject substrate 20 is subjected to surface treatment according to the sequence shown in FIG. 2 using the plasma etching equipment 10 shown in FIG. 3.

First, an SOS substrate 20, in which an SOI layer 12 is formed on a sapphire substrate 11 and a polysilicon layer 13 is formed on the rear and side surfaces of the insulating substrate 11, is placed on an electrostatic chuck 18. Then, after a reaction container 15 is evacuated, a DC power source 23 applies an electrostatic chuck voltage of +2500V, which is a first electrostatic chuck voltage HV1, to the electrostatic chuck 18 for 5 seconds.

Then, an He gas, which is a cooling gas, is introduced through a rear-surface gas introduction path 28 and the inner pressure is controlled at a constant level of 40 Torr and the temperature of the SOS substrate 20 is controlled at 40° C.

Simultaneously with the introduction of the rear-surface He gas, an Ar gas which is a reactive gas is introduced into the reaction container 15 by opening a valve (not shown) of a reactive gas supply system 32. The Ar gas is introduced at a constant flow rate of 500 ssccm and a valve (not shown) of an exhaust system 34 is opened such that the inner pressure of the reaction container 15 reaches a constant level of 30 mTorr.

Thereafter, the electrostatic chuck voltage is changed from +2500V, which is the first electrostatic chuck voltage HV1, to +1500V, which is the second electrostatic chuck voltage HV2, and is maintained at +1500V for 2 seconds. Then, 1 second after the electrostatic chuck voltage is reduced to +1500, an RF power source 21 applies an RF output of 1500 W to the upper electrode 16 and, at the same time, an RF power source 22 applies an RF output of 800 W to the lower electrode 17.

Finally, the electrostatic chuck voltage is returned from +1500V, which is the first electrostatic chuck voltage HV1, to +2500V, which is the third electrostatic chuck voltage HV3. Then, after the SOI layer 12 of the SOS substrate 20 is subjected to surface treatment, the RF output and the electrostatic chuck voltage are reduced to zero, terminating the surface treatment.

These processes were repeated for 10 SOS substrates to perform surface treatment on the substrates and the following estimation was conducted.

—Change of Voltage of SOI Layer—

As shown in FIG. 3, a high-impedance strobe 27 of 100 MO was connected to the SOI layer 12 of the SOS substrate 20 and a digital storage oscilloscope was used to measure the voltage of each location to estimate the time dependency of the voltage as shown in FIG. 4A. Then, an average of the potential difference at points corresponding to the points A and B of FIG. 4A was obtained. The results are shown in Table 1 described later.

—Occurrence of Arcing—

The occurrence of arcing during the processes described above was observed both visually and through measurement using the same oscilloscope as described above and the degree of arcing was then estimated based on the following criteria. The results are shown in Table 1.

\textcircled{◯}: No arcing was measured.

◯: Small arcing was measured and defects or the like were not observed on any SOS substrates.

Δ: Large arcing was measured and cracks were observed on 1 to 3 SOS substrates.

×: Large arcing was measured and cracks were observed on all 10 SOS substrates.

—Misalignment of Substrate—

Whether or not an SOS substrate has moved from its initial position until surface treatment is terminated after the SOS substrate is placed on the electrostatic chuck was estimated based on the following criteria. The results are shown in Table 1.

\textcircled{◯}: No movement of the substrate was observed.

◯: The substrate moved a little but the movement did not disrupt the surface treatment of the SOI layer.

×: The substrate moved such that a desired surface treatment could not be performed on the SOI layer.

### Embodiment 6

The sixth embodiment is similar to the fifth embodiment, except the second electrostatic chuck voltage HV2 is set to 2000V. Surface treatment was performed on an SOS substrate and the same estimation was conducted. The results are shown in Table 1.

### Embodiment 7

The seventh embodiment is similar to the fifth embodiment, except the second electrostatic chuck voltage HV2 is set to 1000V. Surface treatment was performed on an SOS substrate 20 and the same estimation was conducted. The results are shown in Table 1.

[Comparison 1]

The first comparison is similar to the fifth embodiment, except that it employs a sequence in which the electrostatic chuck voltage is not reduced and is instead maintained at a constant level of −2500V. Surface treatment was performed on an SOS substrate and the same estimation was conducted. The results are shown in Table 1.

[Comparison 2]

In the second comparison, after reactive gases are introduced, an RF output of 500 W is applied to excite plasma and then the RF output is temporarily reduced to 0 W as shown in FIG. 6. Then, an electrostatic chuck voltage of +2500V is applied and an RF output of 1500 W is applied from the first high-frequency power source 21 to the upper electrode 16 and an RF output of 800 W is applied from the second high-frequency power source 22 to the lower electrode 17 in the same manner. While other conditions were the same as those of the fifth embodiment, surface treatment was performed on the SOS substrate and the same estimation was conducted. The results are shown in Table 1.

[Comparison 3]

The third comparison is similar to the fifth embodiment, except that it employs a sequence in which the electrostatic chuck voltage is applied after the RF output is applied as shown in FIG. 7A. Surface treatment was performed on an SOS substrate and the same estimation was conducted. The results are shown in Table 1.

[Comparison 4]

The fourth comparison is similar to the fifth embodiment, except that it employs a sequence in which, as shown in FIG. 7B, the electrostatic chuck voltage is applied after the RF output is applied and then the RF output is temporarily reduced to 0 W, and a rear-surface He gas, which is a cooling gas, is introduced and the original RF output is then reapplied. While other conditions were the same as those of the fifth embodiment, surface treatment was performed on the SOS substrate and the same estimation was conducted. The results are shown in Table 1.

[Comparison 5]

The fifth comparison is similar to the first comparison, except that it employs a sequence in which the electrostatic chuck voltage is set to 500V. Surface treatment was performed on an SOS substrate and the same estimation was conducted. The results are shown in Table 1.

TABLE 1

| | | Potential | | |
|---|---|---|---|---|
| | Electrostatic | Difference in SOI | | |
| | Chuck Voltage | layer when RF | | Substrate |
| | [V] | output is applied | Arcing | Movement |
| Embodiment 5 | 1500 | 2500 | ⊚ | ⊚ |
| Embodiment 6 | 2000 | 3333 | ⊚ | ⊚ |
| Embodiment 7 | 1000 | 1666 | ⊚ | ◯ |
| Comparison 1 | −2500 | 4166 | X | ⊚ |
| Comparison 2 | 2500 | 4166 | X | ⊚ |
| Comparison 3 | 2500 | 4166 | X | ⊚ |
| Comparison 4 | 2500 | 4166 | ⊚ | X |
| Comparison 5 | 500 | 833 | ⊚ | X |

As described above, in the embodiments, it is possible to suppress the occurrence of arcing since the RF output is applied to reduce the potential difference. In addition, it is possible to perform desired surface treatment on a substrate with almost no movement of the substrate since the electrostatic chuck voltage is always applied.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic cross-sectional view of semiconductor production equipment according to an embodiment of the present invention;

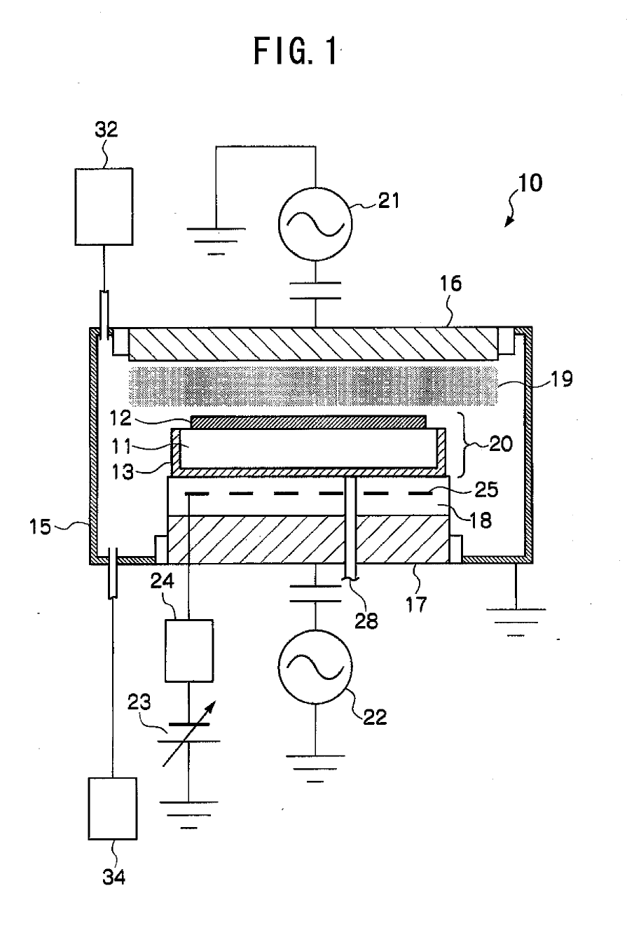

FIG. 2 illustrates a sequence of a method for manufacturing a semiconductor device according to the embodiment of the present invention;

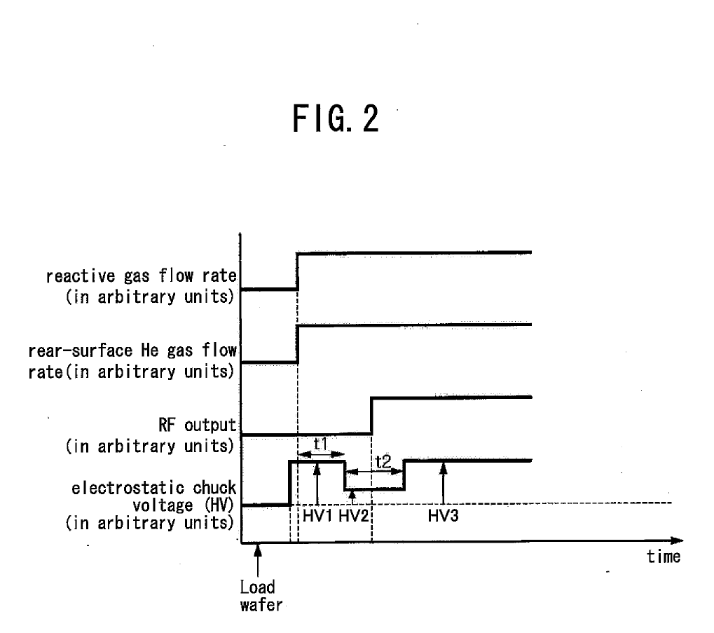

FIG. 3 is a schematic cross-sectional view of semiconductor production equipment for measuring potentials of a polysilicon layer and an SOI layer of a substrate;

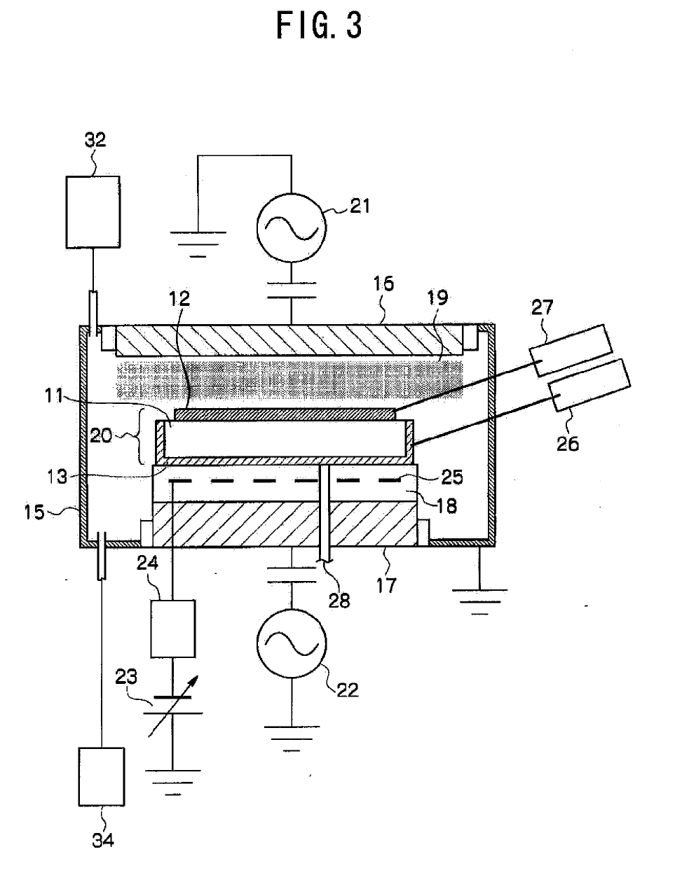

FIG. 4A illustrates the time dependency of voltage of an SOI layer in a conventional sequence in which an RF output is applied while an electrostatic chuck voltage is fixed and FIG. 4B illustrates the time dependency of voltage of a polysilicon layer in a conventional sequence in which an RF output is applied while an electrostatic chuck voltage is fixed;

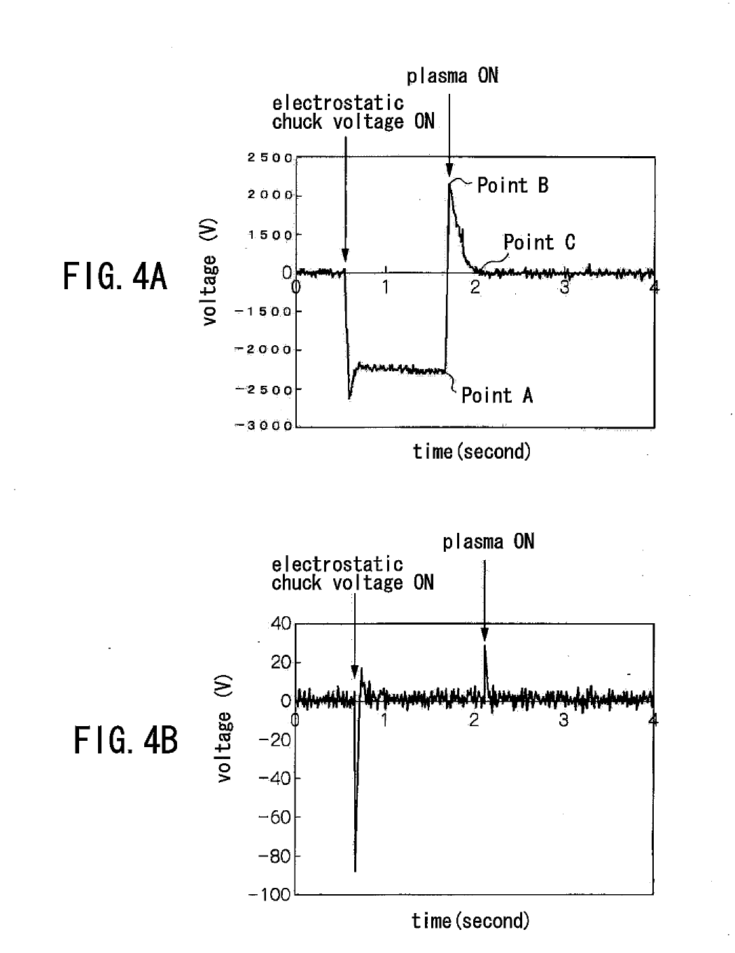

FIG. 5 is a schematic cross-sectional view of semiconductor production equipment when arcing has occurred;

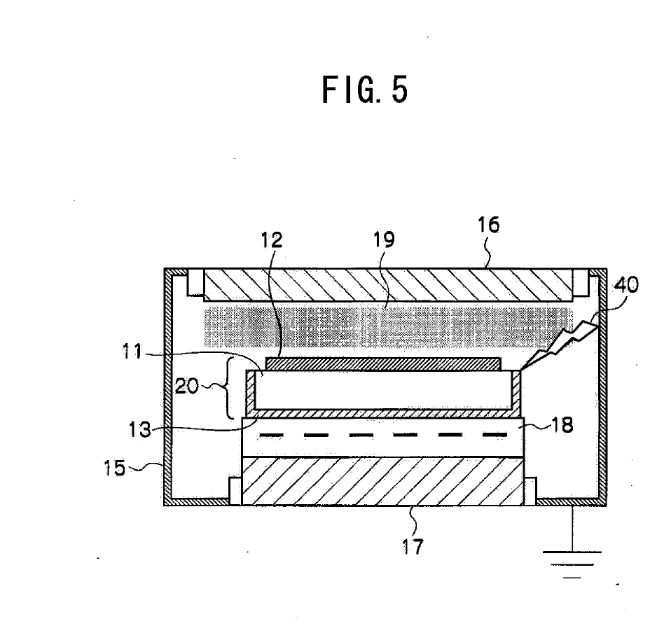

FIG. 6 illustrates a sequence of an example conventional method for manufacturing a semiconductor device; and

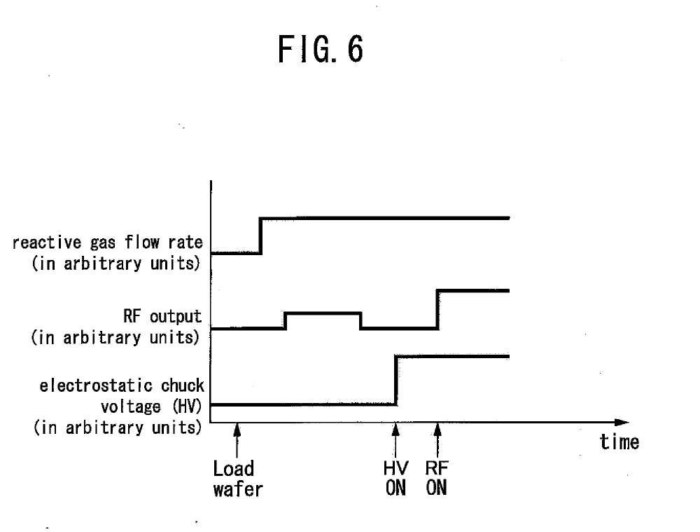

FIGS. 7A and 7B illustrate sequences of example conventional methods for manufacturing a semiconductor device.

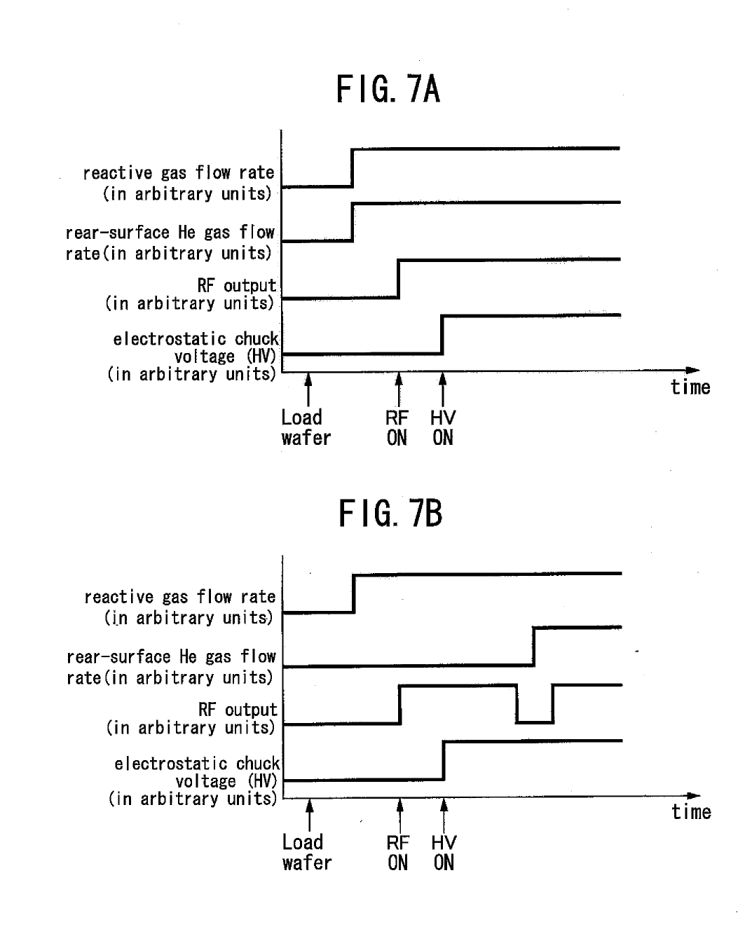

This application is based on Japanese Patent Application No. 2008-164731, the contents of which are incorporated herein by reference in their entirety.

What is claimed is:

1. A method for manufacturing a semiconductor device, the method comprising:
a first process of placing a substrate on an electrostatic chuck in a reaction container and applying a first electrostatic chuck voltage to said electrostatic chuck to absorb said substrate onto said electrostatic chuck;
a second process of reducing said first electrostatic chuck voltage to a second electrostatic chuck voltage;
a third process of applying a high-frequency voltage between parallel plate electrodes in said reaction container to generate plasma; and
a fourth process of changing said second electrostatic chuck voltage to a third electrostatic chuck voltage higher than said second electrostatic chuck voltage.

2. The method according to claim 1, wherein a polysilicon layer is formed on a rear surface of said substrate or rear and side surfaces of said substrate.

3. The method according to claim 2, wherein said polysilicon layer is a doped polysilicon layer.

4. The method according to claim 1, wherein said second electrostatic chuck voltage is equal to or higher than 1000V and equal to or less than 2000V.

5. The method according to claim 1, further comprising a process of introducing a reactive gas into the reaction container and introducing a cooling gas to an absorbing surface of said substrate before said third process.

6. Semiconductor production equipment comprising:
a reaction container;
an upper electrode and a lower electrode that are provided opposite each other in said reaction container;
a first high-frequency power source that applies high-frequency power to said upper electrode;
a second high-frequency power source that applies high-frequency power to said lower electrode;
an electrostatic chuck that electrostatically absorbs a substrate in said reaction container;
a DC power source that applies an electrostatic chuck voltage to said electrostatic chuck;
a reactive gas supply system that supplies a reactive gas for generating plasma into said reaction container; and
a controller,
wherein the controller sequentially performs:
a first process of controlling said DC power source so as to apply a first electrostatic chuck voltage for absorbing said substrate onto said electrostatic chuck to said electrostatic chuck;
a second process of controlling said DC power source so as to change said first electrostatic chuck voltage to a second electrostatic chuck voltage lower than said first electrostatic chuck voltage;
a third process of controlling said first and second high-frequency power sources so as to apply a high-frequency voltage for generating plasma in said reaction container between said upper and lower electrodes; and
a fourth process of controlling said DC power source so as to change said second electrostatic chuck voltage to a third electrostatic chuck voltage higher than said second electrostatic chuck voltage.

7. The semiconductor production equipment according to claim 6, wherein a polysilicon layer is formed on a rear surface of said substrate or rear and side surfaces of said substrate.

8. The semiconductor production equipment according to claim 7, wherein the polysilicon layer is a doped polysilicon layer.

9. The semiconductor production equipment according to claim 6, wherein second electrostatic chuck voltage is equal to or higher than 1000V and equal to or less than 2000V.

10. The semiconductor production equipment according to claim 6, wherein, before said third process, said controller performs a process of introducing the reactive gas into said reaction container and introducing the cooling gas to an absorbing surface of said substrate.

11. A storage medium storing a program that is executed by a controller of semiconductor production equipment including a reaction container,
wherein the program includes:
a first step of applying a first electrostatic chuck voltage to an electrostatic chuck in the reaction container to absorb a substrate onto said electrostatic chuck;
a second step of changing said first electrostatic chuck voltage to a second electrostatic chuck voltage lower than said first electrostatic chuck voltage;
a third step of applying a high-frequency voltage between parallel plate electrodes in said reaction container to generate plasma in said reaction container; and
a fourth step of changing said second electrostatic chuck voltage to a third electrostatic chuck voltage higher than said second electrostatic chuck voltage.
